(19) United States
(12) Patent Application Publication
(10) Pub. No.: US 2015/0221809 A1
(43) Pub. Date: Aug. 6, 2015

(54) SEMICONDUCTOR DEVICE MANUFACTURING METHOD

(71) Applicant: CANON KABUSHIKI KAISHA, Tokyo (JP)

(72) Inventors: Rei Kurashima, Yokohama-shi (JP); Takayuki Sumida, Kawasaki-shi (JP)

(21) Appl. No.: 14/593,104

(22) Filed: Jan. 9, 2015

(30) Foreign Application Priority Data
Feb. 5, 2014 (JP) 2014-020748

(51) Int. Cl. H01L 31/18; H01L 31/0216; H01L 21/308; H01L 31/0232

(52) U.S. Cl. CPC H01L 31/1804; H01L 31/02327; H01L 31/02162; H01L 21/3085

(57) ABSTRACT

A semiconductor device manufacturing method, comprising a first step of forming, on a silicon substrate, a member having an opening through which a portion of an upper surface of the silicon substrate is exposed so as to be an exposed face, and a second step of etching the member by supplying an etching gas containing XeF₂ to the exposed face and the member, such that a thickness of the member increases in a direction away from the exposed face.

### BACKGROUND OF THE INVENTION

1. Field of the Invention

The present invention relates to a semiconductor device manufacturing method.

2. Description of the Related Art

A semiconductor device for performing spectral analysis on incident light includes, for example, an image capturing element formed on a substrate, and a spectrum element formed on the image capturing element. The spectrum element has a structure for spectrally dividing incident light on the upper surface thereof.

Japanese Patent Laid-Open No. 2013-512445 has disclosed a method of forming an inclined structure having a stepped upper surface, which forms a part of the spectrum element. In this method disclosed in Japanese Patent Laid-Open No. 2013-512445, a stepped inclined structure having 2^{N} steps is formed by performing an etching step N times. Since the etching step must be performed many times in the method of Japanese Patent Laid-Open No. 2013-512445, the yield may decrease or the manufacturing cost may increase.

### SUMMARY OF THE INVENTION

It is an object of the present invention to provide a technique advantageous in increasing the yield and reducing the manufacturing cost in a method of manufacturing a semiconductor device including a structure having an inclined face.

One of the aspects of the present invention provides a semiconductor device manufacturing method, comprising a first step of forming, on a silicon substrate, a member having an opening through which a portion of an upper surface of the silicon substrate is exposed so as to be an exposed face, and a second step of etching the member by supplying an etching gas containing XeF₂ to the exposed face and the member, such that a thickness of the member increases in a direction away from the exposed face.

Further features of the present invention will become apparent from the following description of exemplary embodiments with reference to the attached drawings.

### BRIEF DESCRIPTION OF THE DRAWINGS

FIG. 1 is a view for explaining an arrangement example of a semiconductor device.

FIGS. 2A and 2B are views for explaining an example of a semiconductor device manufacturing method.

FIG. 3 is a view for explaining an example of the semiconductor device manufacturing method.

FIGS. 4A and 4B are views for explaining an example of the semiconductor device manufacturing method.

FIGS. 5A and 5B are views for explaining an example of the semiconductor device manufacturing method.

FIGS. 6A and 6B are views for explaining an example of the semiconductor device manufacturing method.

### DESCRIPTION OF THE EMBODIMENTS

### 1. First Embodiment

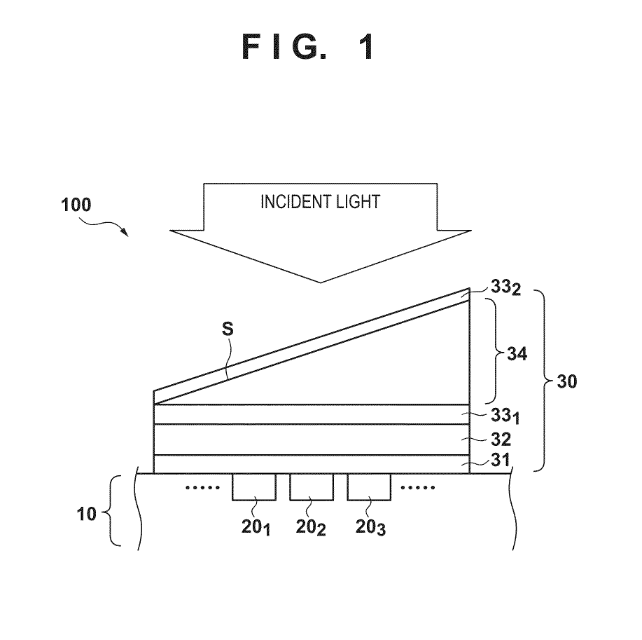

A semiconductor device 100 according to the first embodiment and a method of manufacturing the same will be described below with reference to FIGS. 1 to 4B.

1.1 Arrangement Example of Semiconductor Device

An arrangement example of the semiconductor device 100 will be described with reference to FIG. 1. The semiconductor device 100 can include a plurality of image capturing elements 20 (for example, 20₁, 20₂, and 20₃) formed on a silicon substrate 10, and a spectrum element 30 formed on the plurality of image capturing elements 20. The plurality of image capturing elements 20 are sensors for sensing light, such as CCD image sensors or CMOS image sensors.

The spectrum element 30 can include a planarization film 31, color filter 32, first reflecting film 33₁, structure 34, and second reflecting film 33₂. The planarization film 31 (a planarization layer) is formed on the substrate 10, and planarizes the roughness of the upper surface of the substrate 10. The filter 32 is formed on the planarization film 31, and can be formed by an organic material having a predetermined color. The reflecting film 33₁ is formed on the color filter 32. The structure 34 is formed on the reflecting film 33₁, and has an inclined face S inclined to the upper surface of the substrate 10. The reflecting film 33₂ is formed on the inclined face S of the structure 34.

The reflecting films 33₁ and 33₂ can function as an etalon of a Fabry-Perot interferometer. The reflecting films 33₁ and 33₂ can be formed by, for example, a half mirror (semitransparent mirror), dielectric mirror, or air interface. It is also possible to form a solid etalon or air-gap etalon. A light-reflecting thin-film member (having a film thickness of about 10 to 50 nm) is used as the half mirror, and it is possible to use, for example, a metal such as aluminum (Al) or silver (Ag), or a compound thereof. The dielectric mirror has a small light absorptance and large light reflectance when compared to metals. For example, it is possible to use the half mirror as the reflecting film 33₁, and one of the half mirror, dielectric mirror, and air interface as the reflecting film 33₂.

The plurality of image capturing elements 20 can be arranged in a line or array along the inclination of the inclined face S of the structure 34. Incident light entering the image capturing elements 20 through the spectrum element 30 is different in wavelength for each interval between the image capturing elements (between the image capturing elements 20₁, 20₂, and 20₃ in FIG. 1). For example, light having a wavelength λ₁ enters the image capturing element 20₁, light having a wavelength λ₂ enters the image capturing element 20₂, and light having a wavelength λ₃ enters the image capturing element 20₃. That is, since the structure 34 has the inclined face, the optical path length of the incident light changes from one image capturing element to another, so the wavelengths of light received by the image capturing elements are shifted from each other.

When the light reflectance of the reflecting films 33₁ and 33₂ is increased and the FWHM (Full Width at Half Maximum) of the dependence of the transmittance on the wavelength (the transmittance spectrum) is decreased, it is possible to perform high-resolution spectral analysis or high-accuracy wavelength measurement.

Also, to increase the wavelength resolution of the etalon, a high order of interference such as a second order or third order is used instead of first-order interference. This makes it possible to decrease the FWHM of the filter (to about 10 nm) while maintaining the reflectance of the reflecting film. In this case, however, an unnecessary transmission band may be formed near a desired wavelength band in the transmittance spectrum, so the color filter 32 is preferably formed by using a material having a color which removes the unnecessary transmission band. The color filter 32 can be formed by one color or a combination of two or more colors in accordance with a wavelength band to be removed. For example, it is possible to form a bandpass filter having continuous band boundaries between blue and green and between green and red by combining cyan and yellow color filters with red, green, and blue color filters. It is also possible to use an IR color filter which transmits infrared light. It is only necessary to prepare a resist agent having a desired color, and form the color filter 32 in a desired position by using, for example, a photolithography technique.

1.2 Example of Semiconductor Device Manufacturing Method

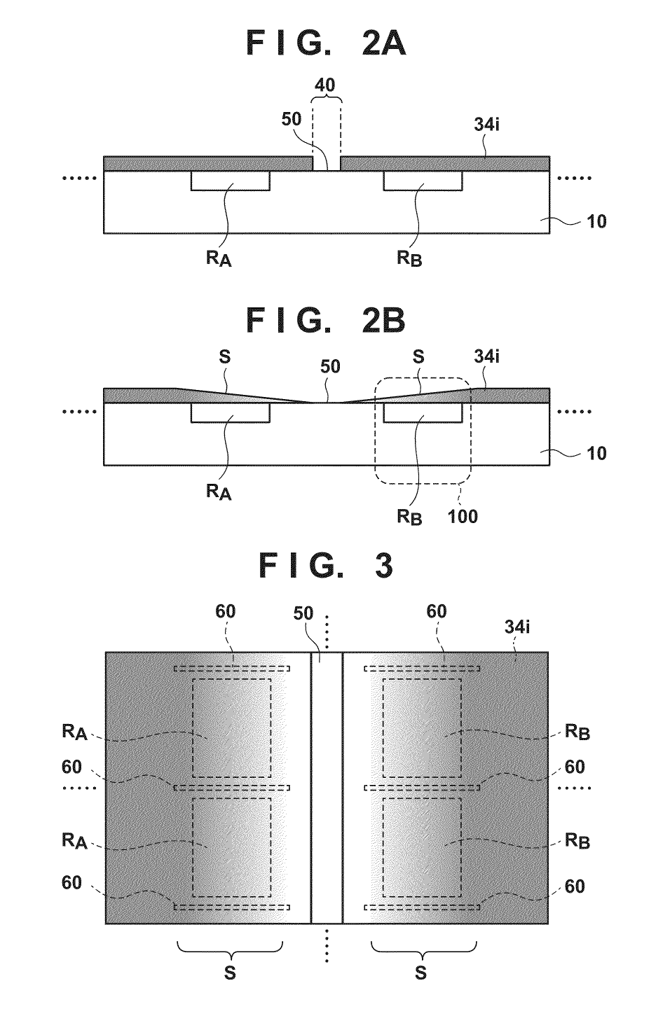

An example of a method of manufacturing the semiconductor device 100 will be described with reference to FIGS. 2A, 2B, and 3.

First, in a step shown in FIG. 2A, two image capturing regions R (R_{A} and R_{B}), for example, are formed in a silicon substrate 10. A plurality of image capturing elements 20 described above are formed in each image capturing region R. Then, a planarization film 31, color filter 32, and reflecting film 33₁ (not shown) are sequentially formed on the silicon substrate 10. After that, a member (to be referred to as “a member 34i” hereinafter) for forming a structure 34 is formed on top of these films. Although silicon nitride is used as the member 34i in this embodiment, it is also possible to use silicon oxide, silicon oxynitride, or the like.

After that, the planarization film 31, color filter 32, reflecting film 33₁, member 34i are partially removed by using, for example, a photolithography technique, so as to expose a portion of the upper surface of the silicon substrate 10, thereby forming an opening 40. FIG. 2A shows the exposed face of the substrate 10 as “an exposed face 50”. Note that the opening 40 and exposed face 50 may also be formed by forming the planarization film 31, color filter 32, reflecting film 33₁, and member 34i on a portion of the silicon substrate 10 (that is, on a region except for the exposed face 50).

Subsequently, in a step shown in FIG. 2B, the structure obtained in the step shown in FIG. 2A is etched by using an etching gas containing XeF₂. In this step, the substrate 10 (silicon) and the member 34i near the exposed face 50 are etched.

More specifically, a reaction formula in the above-mentioned etching step is:

Si+2XeF₂→SiF₄+2Xe

In this step, the member 34i (silicon nitride in this embodiment) can be etched when silicon exists nearby. This is so because a byproduct formed by the above-mentioned reaction contributes to the etching of the member 34i. As shown in FIG. 2B, therefore, when the etching gas containing XeF₂ is supplied to the exposed face 50 and member 34i, an inclined face S inclined along the direction away from the exposed face 50 is formed on the member 34i. In other words, the etching amount of a portion of the member 34i, which is close to the exposed face 50 of the silicon substrate 10, is larger than that of a portion of the member 34i, which is far from the exposed face 50 of the silicon substrate 10. Note that “the etching amount” means an etching amount in a direction perpendicular to the upper surface of the silicon substrate 10.

In the step shown in FIG. 2B described above, a portion where silicon is exposed exists, and the member 34i near this portion is etched. As a result, the member 34i is shaped, and the inclined face S is formed on it.

Since the member 34i is etched near the portion where silicon is exposed, the inclination of the inclined face S is so formed as to increase the thickness of the member 34i along the direction away from the exposed face 50 of the substrate 10. When forming the inclined face S in one direction, therefore, the opening 40 for forming the exposed face 50 is preferably formed into the shape of a slit or trench (that is, the outer shape is a rectangle in planar view). In another example, a plurality of openings 40 are formed into an array.

After the step shown in FIG. 2B, a reflecting film 33₂ is so formed as to cover the inclined face S, and dicing is performed for each chip. Thus, the semiconductor device 100 in which the image capturing element 20 and spectrum element 30 are integrated is obtained.

Note that this embodiment uses the substrate 10 simply formed by silicon, but silicon includes single-crystal silicon, polycrystalline silicon, and amorphous silicon. When using polycrystalline silicon or amorphous silicon, silicon is formed on the substrate by a deposition method such as sputtering or CVD, and patterned by using a photolithography technique.

FIG. 3 is a schematic view for explaining a part of the layout on the wafer after the step shown in FIG. 2B. The exposed face 50 (or the above-described opening 40) of the substrate 10 is formed between the pair of image capturing regions R (R_{A} and R_{B}). In FIG. 3, the direction from the image capturing region R_{B} to the image capturing region R_{A} is a first direction D_{A}, and the direction from image capturing region R_{A} to the image capturing region R_{B} is a second direction D_{B}. The member 34i on the image capturing region R_{A} is so shaped as to have the inclined face S which is inclined so as to increase the thickness along the direction D_{A} from the exposed face 50. The member 34i on the image capturing region R_{B} is so shaped as to have the inclined face S which is inclined so as to increase the thickness along the direction D_{B} from the exposed face 50.

Also, a TEG pattern 60 for checking the characteristics of the spectrum element 30 and the corresponding image capturing element 20 is preferably formed in the boundary region of the chip regions, for example, between adjacent image capturing regions R_{A} or adjacent image capturing regions R_{B}. The dimensions of the structure 34 formed in the above-described etching step and the inclination of the inclined face S of the structure 34 depend on various conditions of the etching. Therefore, the dimensions of the actually formed structure 34 and the inclination of the inclined face S of the structure 34 are deviated from design values or target values. Accordingly, the characteristic of the spectrum element 30 (the spectral characteristic or optical film thickness in each position on the inclined face of the structure 34) can be acquired by measuring the TEG pattern 60. The TEG pattern 60 is preferably formed such that the dimensions are the same as those of the spectrum element 30, and the distance to the exposed face 50 is equal to the distance between the spectrum element 30 and exposed face 50.

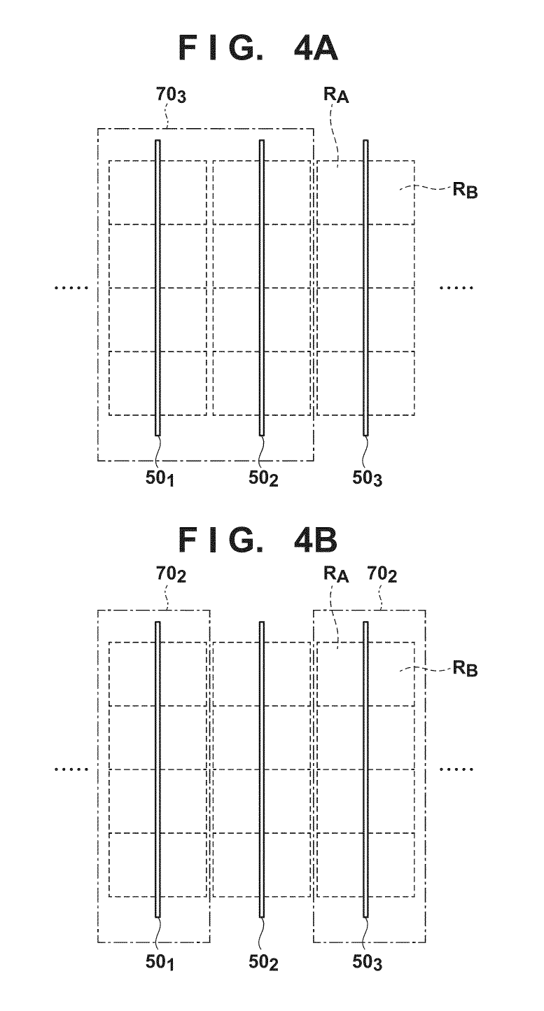

The etching amount of the member 102 depends on the etching conditions such as the pressure, flow rate, and temperature of XeF₂ as an etching gas, and on the layout on the wafer such as the area of the exposed face 50. If a plurality of exposed faces 50 exist, therefore, one exposed face 50 may have influence on the etching amount of the member 34i near another exposed face 50. Accordingly, instead of performing the above-described etching step on the entire wafer surface at once, it is preferable to form a resist pattern for exposing some (or one) of the plurality of exposed faces 50, etch the some exposed faces 50, and similarly etch other exposed faces 50 after that. FIGS. 4A and 4B each show three exposed faces 50 (50₁ to 50₃), and the pair of image capturing regions R (R_{A} and R_{B}) formed on the two sides of each exposed face 50. First, as shown in FIG. 4A, a resist pattern 70₃ is so formed as to expose the exposed face 50₃ and (the member 34i on) the image capturing region R corresponding to the exposed face 50₃. That is, the resist pattern 70₃ is so formed as to cover the exposed faces 50₁ and 50₂ and (the members 34i on) the image capturing regions R corresponding to the exposed faces 50₁ and 50₂. After that, etching using XeF₂ as an etching gas is performed. Consequently, the structure 34 having the inclined face S is formed on the image capturing region R corresponding to the exposed face 50₃.

Then, as shown in FIG. 4B, a resist pattern 70₂ is so formed as to expose the exposed face 50₂ and (the member 34i on) the image capturing region R corresponding to the exposed face 50₂, and etching is performed, in the same manner as described above. After that, etching is similarly performed (not shown) on the exposed face 50₁ and (the member 34i on) the image capturing region R corresponding to the exposed face 50₁. Thus, an etching target region is divided into several regions, and the divided regions are sequentially etched by using resist patterns each of which covers a portion except for a divided region to be etched.

1.3 Examples of Experimental Results

The results of experiments conducted based on the above-mentioned manufacturing method will be presented below.

CMOS image sensors having a 35-mm full size were formed as a plurality of image capturing elements 20, and a spectrum element 30 having a red light band as a transmission band was formed. A red color filter was used as the color filter 32. Ag-compound films (film thickness=40 nm) formed by sputtering were used as the reflecting films 33₁ and 33₂. Silicon nitride (film thickness=650 nm) formed by PECVD was used as the member 34i. The exposed face 50 of the substrate 10 for forming the spectrum element 30 was formed by forming a slit-like opening 40 having a width of 1.0 mm in the member 34i.

The etching step using XeF₂ as an etching gas was performed using an etching apparatus available from Memsstar. The etching conditions were that the temperature of the substrate 10 was 15° C., the pressure was 2 Torr, the flow rate of a carrier gas (N₂) was 50 sccm, and the etching time was 100 sec.

In the structure 34 formed as described above, the film thickness of a portion which transmitted light having a wavelength of 600 nm was about 395 nm, and that of a portion which transmitted light having a wavelength of 800 nm was about 550 nm.

### 2. Second Embodiment

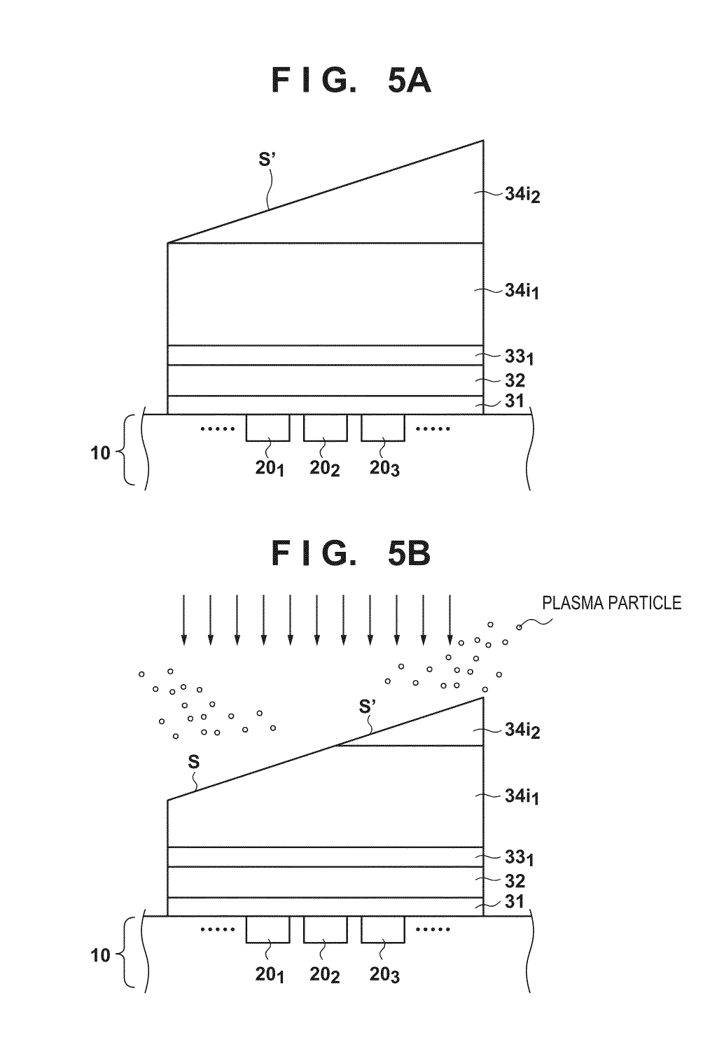

The second embodiment will be explained with reference to FIGS. 5A and 5B.

A main difference of this embodiment from the above-described first embodiment is that a structure 34 having an inclined face S is formed by a transfer method using two members. More specifically, in a step of forming the structure 34, a first member 34i₁ for forming the structure 34 is formed first, and then a second member 34i₂ is formed on the member 34i₁. After that, as exemplarily shown in FIG. 5A, the member 34i₂ is so shaped as to have an inclined face S′. In addition, as exemplarily shown in FIG. 5B, the shape of the shaped member 34i₂ is transferred to the member 34i₁.

This embodiment is advantageous in adjusting the structure 34 to have desired dimensions, thereby adjusting the inclined angle of the inclined face S of the structure 34.

For example, when the wavelength band of visible light is a target, a material having a refractive index of about 1.45 is used as the member 34i₁, and the structure 34 is formed such that a film thickness difference on the slope is about a few hundred nm. It is possible to use, for example, silicon oxide or silicon oxynitride as the member 34i₁, and use, for example, silicon nitride as the member 34i₂. In this embodiment, different materials are used as the members 34i₁ and 34i₂, and the structure 34 having the inclined face S having a large inclined angle is formed by using the difference between the etching rates of these materials.

An example of the method of transferring the shape of the member 34i₂ on which the inclined face S′ is formed to the member 34i₁ is a method using high-frequency plasma etching. For example, the structure 34 can be formed such that the final inclined face S forms a desired inclined angle, by appropriately adjusting, for example, the etching selectivity (etching rate ratio) between the members 34i₁ and 34i₂, the incident direction of plasma particles, and the plasma power. It is also possible to properly select and set other etching conditions.

After that, a reflecting film 33₂ is so formed as to cover the inclined face S, and dicing is performed for each chip, in the same manner as in the above-described first embodiment.

The results of experiments conducted based on the above-mentioned method will be presented below.

CMOS image sensors having a 35-mm full size were formed as a plurality of image capturing elements 20, and a spectrum element 30 having a green light band as a transmission band was formed. A green color filter was used as a color filter 32. Ag-compound films (film thickness=40 nm) formed by sputtering were used as the reflecting films 33₁ and 33₂. Silicon oxide (film thickness=600 nm) formed by PECVD was used as the member 34i₁. Silicon nitride (film thickness=650 nm) formed by PECVD was used as the member 34i₂. An exposed face 50 of a substrate 10 for forming the spectrum element 30 was formed by forming slit-like openings 40 having a width of 1.0 mm in the members 34i₁ and 34i₂.

The step shown in FIG. 5A (the step of forming the member 34i₂ so as to have an inclined face) was performed in the same manner as in the above-described first embodiment. That is, an etching step using XeF₂ as an etching gas was performed using the etching apparatus available from Memsstar. The etching conditions were that the temperature of the substrate 10 was 15° C., the pressure was 2 Torr, the flow rate of a carrier gas (N₂) was 50 sccm, and the etching time was 100 sec.

The step shown in FIG. 5B (the step of transferring the shape of the shaped member 34i₂ to the member 34i₁) was performed by forming a resist pattern for exposing the shaped member 34i₂ on the structure obtained in FIG. 5A, and performing the above-described high-frequency plasma etching.

In the structure 34 formed as described above, the film thickness of a portion which transmitted light having a wavelength of 480 nm was about 440 nm, and that of a portion which transmitted light having a wavelength of 600 nm was about 565 nm.

### 3. Third Embodiment

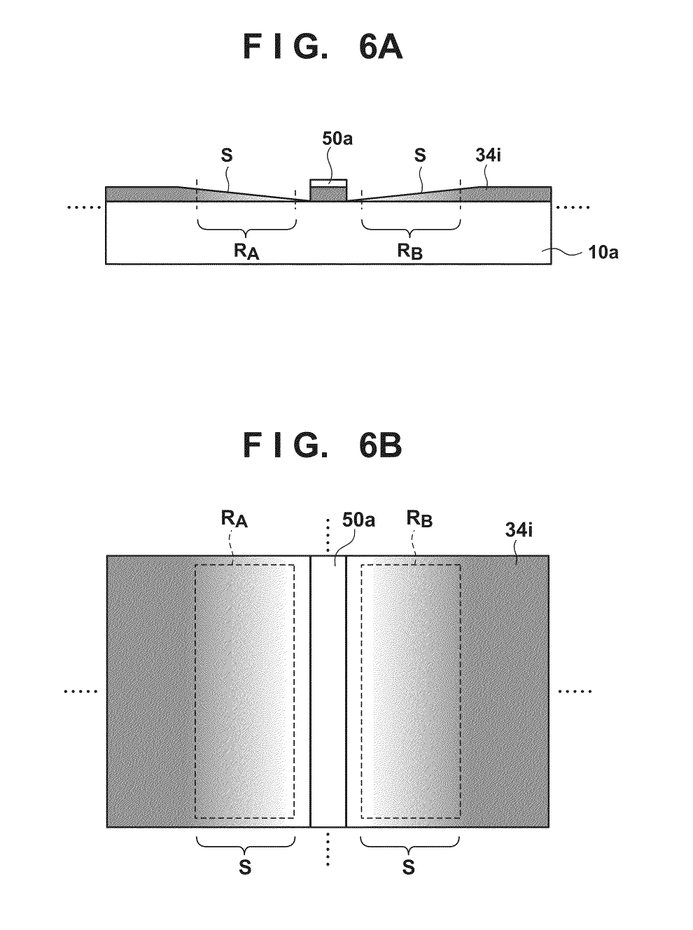

The third embodiment will be explained with reference to FIGS. 6A and 6B. A main difference of this embodiment from the above-described first embodiment is that a semiconductor device 100 is manufactured on a glass substrate 10a (or another light-transmitting substrate). In this embodiment, therefore, a silicon-exposed portion is formed on the glass substrate 10a before a step of forming a structure 34 by shaping a member 34i.

FIG. 6A is a schematic view showing a sectional structure after the member 34i formed on the glass substrate 10a is shaped so as to form an inclined face S. FIG. 6B is a plan view of the structure.

First, a planarization film 31, color filter 32, and reflecting film 33₁ described above (none of them is shown) are sequentially formed on a glass substrate 10a on which a plurality of sensors (not shown) are formed. Note that the plurality of sensors can be formed by using, for example, amorphous silicon.

Then, a member 34i is formed on the glass substrate 10a, and a silicon pattern 50a is formed on the member 34i. The silicon pattern 50a is formed between two image capturing regions R (R_{A} and R_{B}) formed by the plurality of sensors described above, by depositing an amorphous silicon member on the member 34i, and patterning the amorphous silicon member.

The above-described etching (etching using XeF₂ as an etching gas) is performed on the structure thus obtained. Since the silicon pattern 50a exists, the member 34i near the silicon pattern 50a is etched. As a consequence, the member 34i is shaped, and an inclined face S is formed on the member 34i.

After that, a reflecting film 33₂ is so formed as to cover the inclined face S, and dicing is performed for each chip, in the same manner as in the above-described first embodiment.

In experiments conducted based on the above-mentioned manufacturing method, the same experimental results as in the first embodiment were obtained. Note that the silicon pattern 50a was obtained by patterning the amorphous silicon member (film thickness=4 μm) formed on the member 34i into the shape of a slit having a width of 1.0 mm, and other steps were performed in the same manner as in the above-described first embodiment.

### 4. Others

The three embodiments have been described above, but the present invention is not limited to these embodiments, and it is possible to partially change the embodiments or combine the embodiments without departing from the spirit and scope of the invention in accordance with, for example, the purpose of the invention. For example, the transfer method (the second embodiment) which forms the structure 34 by using the two members 34i₁ and 34i₂ may also be applied to the mode (the third embodiment) which forms the structure 34 on the glass substrate 10a.

Also, the semiconductor device in which the spectrum element and image capturing element are integrated is exemplified in each of the above embodiments, but an application example of the present invention is not limited to the above-mentioned mode, and the invention is applicable to other semiconductor devices. For example, the semiconductor device includes an optical element formed on a glass substrate, and an element for use in MEMS (Micro Electro Mechanical Systems). Note that each of these elements need not contain a semiconductor after manufacture, but is included in the concept of a semiconductor device because silicon is used in the manufacture.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-020748, filed Feb. 5, 2014, which is hereby incorporated by reference herein in its entirety.

What is claimed is:

1. A semiconductor device manufacturing method comprising:
a first step of forming, on a silicon substrate, a member having an opening through which a portion of an upper surface of the silicon substrate is exposed so as to be an exposed face; and
a second step of etching the member by supplying an etching gas containing XeF₂ to the exposed face and the member, such that a thickness of the member increases in a direction away from the exposed face.

2. A semiconductor device manufacturing method comprising:
a first step of forming, on a silicon substrate, a member having an opening through which a portion of an upper surface of the silicon substrate is exposed so as to be an exposed face; and
a second step of etching the member by supplying an etching gas containing XeF₂ to the exposed face and the member, such that an etching amount of a first portion of the member is larger than that of a second portion of the member, which is farther from the exposed face than the first portion.

3. The method according to claim 1, wherein the opening includes a trench having a rectangular outer shape in planar view with respect to the upper surface of the silicon substrate.

4. The method according to claim 1, further comprising a step of forming an image capturing element on the silicon substrate before the first step.

5. The method according to claim 4, wherein the member forms at least a part of a spectrum element.

6. The method according to claim 5, wherein the spectrum element includes a first light-reflecting film formed below the member, and a second light-reflecting film formed above the member.

7. The method according to claim 1, further comprising a step of dicing the silicon substrate for each chip after the second step.

8. The method according to claim 1, wherein the member is at least one of silicon oxide, silicon nitride, and silicon oxynitride.

9. A semiconductor device manufacturing method comprising:
a first step of forming a member on a silicon substrate, and forming, on the member, a second member different from the member;
a second step of forming an opening in the member and the second member such that a portion of an upper surface of the silicon substrate is exposed so as to be an exposed face;
a third step of etching the second member by supplying an etching gas containing XeF₂ to the exposed face and the second member, such that a thickness of the second member increases in a direction away from the exposed face; and
a fourth step of transferring a shape of the second member to the member after the third step.

10. A semiconductor device manufacturing method comprising:
a first step of forming a member on a silicon substrate, and forming, on the member, a second member different from the member;
a second step of forming an opening in the member and the second member such that a portion of an upper surface of the silicon substrate is exposed so as to be an exposed face;
a third step of etching the second member by supplying an etching gas containing XeF₂ to the exposed face and the second member, such that an etching amount of a first portion of the second member is larger than that of a second portion of the second member farther from the exposed face than the first portion; and
a fourth step of transferring a shape of the second member to the member after the third step.

11. The method according to claim 9, wherein in the fourth step,
the shape of the shaped second member is transferred to the member by etching the second member and the member, and
an etching rate of the member is higher than that of the second member.

12. The method according to claim 9, wherein the member is made of silicon nitride, and the second member is made of at least one of silicon oxide and silicon oxynitride.

13. The method according to claim 1, wherein the first step includes a step of forming a color filter on the silicon substrate, and a step of forming the member on the color filter.

14. The method according to claim 13, wherein
the first step further includes a step of forming a planarization layer which planarizes the upper surface of the silicon substrate, before the step of forming the color filter, and
the color filter is formed on the planarization layer in the step of forming the color filter.

15. A semiconductor device manufacturing method comprising:
a first step of forming a member on a substrate;
a second step of forming a silicon pattern on the member; and
a third step of etching the member by supplying an etching gas containing XeF₂ to the silicon pattern and the member, such that a thickness of the member increases in a direction away from the silicon pattern.

16. A semiconductor device manufacturing method comprising:
a first step of forming a member on a substrate;
a second step of forming a silicon pattern on the member; and
a third step of etching the member by supplying an etching gas containing XeF₂ to the silicon pattern and the member, such that an etching amount of a first portion of the member is larger than that of a second portion of the member, which is farther from the silicon pattern than the first portion.

17. The method according to claim 15, wherein the silicon pattern is formed by using amorphous silicon in the second step.

18. The method according to claim 15, wherein the substrate includes a glass substrate.
